(19) United States
(12) Patent Application Publication
(10) Pub. No.: US 2008/0023814 A1
(43) Pub. Date: Jan. 31, 2008

(54) STACKED BALL GRID ARRAY SEMICONDUCTOR PACKAGE

(75) Inventor: Seung-Yeol YANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/829,851

(22) Filed: Jul. 27, 2007

(30) Foreign Application Priority Data
Jul. 28, 2006 (KR) 2006-71622

(51) Int. Cl. H01L 23/488

(52) U.S. Cl. 257/686; 257/738; 257/E23.023

(57) ABSTRACT

Provided is a stacked ball grid array (BGA) semiconductor package. The stacked BGA semiconductor package includes: a single semiconductor package having landings provided in depressed grooves of both sides thereof, wherein the landings include a conductive material, and a substrate having a semiconductor chip disposed on the substrate; another semiconductor package formed above the single semiconductor package and having landing pads formed in a lower surface of the substrate thereof; and solder balls connecting the landing pads to the landings.

### CROSS-REFERENCE TO RELATED APPLICATIONS

This U.S. non-provisional patent application claims priority under 35 U.S.C. § 119 to Korean Patent Application No. 2006-71622, filed on Jul. 28, 2006, the entire contents of which are hereby incorporated by reference.

### BACKGROUND

1. Technical Field

The present invention disclosed herein relates to a semiconductor package, and more particularly, to a stacked ball grid array (BGA) semiconductor package.

2. Description of the Related Art

Electronic appliances are being developed with the focus on miniaturization, reduced weight, and high speed performance. This has driven many changes in semiconductor device manufacturing in order to keep up with the technological developments of the electronic appliances. Conventional wafer fabrication processes have focused on high integration of semiconductor chips so as to further the miniaturization of the semiconductor devices. However, for the high integration of the semiconductor chips in the wafer fabrication processes, much research and many equipment developments are needed and fabrication cost also increases. As a result, it is difficult to realize the high integration of the semiconductor devices. To solve this problem, technologies for improving the integration of the semiconductor devices by stacking the semiconductor chips or packages are being introduced.

FIGS. 1 and 2 are cross-sectional views of a conventional single BGA semiconductor package and a conventional stacked BGA semiconductor package, respectively.

Referring to FIG. 1, the conventional single BGA semiconductor package 40 includes a semiconductor chip 20 disposed on a substrate 10. The substrate 10 may be implemented using a multi-layer circuit board. The semiconductor chip 20 includes a semiconductor die 24 attached to the substrate 10 using an adhesive tape 22. Bond pads (not shown) of the semiconductor die 24 are connected to bond fingers (not shown) of the substrate 10 through wires 26. The semiconductor die 24 and the wires 26 are encapsulated with an encapsulating resin 28. Solder balls 30 are attached on landing pads 11 formed in a lower surface of the substrate 10.

Referring to FIG. 2, the conventional stacked BGA semiconductor package includes a first semiconductor package 40A stacked on a second semiconductor package 40B. The first semiconductor package 40A includes a first substrate 10a and a first semiconductor chip 20a disposed on the first substrate 10a, and the second semiconductor package 40B includes a second substrate 10b and a second semiconductor chip 20b disposed on the second substrate 10b. First solder balls 30a provided on first landing pads 11a formed in a lower surface of the first substrate 10a contact second landing pads 11b formed in an upper surface of the second substrate 10b to connect the first semiconductor package 40A to the second semiconductor package 40B. Second solder balls 30b are provided on third landing pads 11c formed in a lower surface of the second substrate 10b.

Due to warpage of the first substrate 10a and/or the second substrate 10b, junctions of the first solder balls 30a connecting the first semiconductor package 40A to the second semiconductor package 40B may not be uniform. Furthermore, the first semiconductor package 40A and the second semiconductor package 40B may be physically or electrically disconnected from each other. Also, the overall height of the stacked BGA semiconductor package may increase by the sum (H1+H2) of heights of each of the first and second solder balls 30a and 30b.

Therefore, an integration degree of a semiconductor device is limited when the semiconductor packages are stacked according to the conventional art. Problems with the conventional technologies as described above may obstruct efforts directed to miniaturization and reducing thickness of the stacked semiconductor package.

### SUMMARY

The present invention provides a semiconductor package for improving an integration degree, in which semiconductor packages are stably stacked.

Embodiments of the present invention provide semiconductor packages. The semiconductor packages include: a substrate including landings provided in depressed grooves of both sides of the substrate, and bond fingers formed on an upper surface of the substrate, wherein the landings include a conductive material; a semiconductor chip disposed on the substrate and including bond pads; wires connecting the bond pads to the bond fingers; and an encapsulant encapsulating the semiconductor chip and the wires.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view of a conventional single semiconductor package;

FIG. 2 is a cross-sectional view of a conventional stacked ball grid array (BGA) semiconductor package;

FIG. 3 is a cross-sectional view of a single semiconductor package according to some embodiments of the present invention;

FIGS. 4A through 4C are partial perspective views illustrating landings of a single semiconductor package according to some embodiments of the present invention;

FIGS. 5A through 5E are cross-sectional views illustrating various positions of solder balls in a single semiconductor package according to some embodiments of the present invention; and

FIGS. 6 through 10 are cross-sectional views of a stacked BGA semiconductor package according to some embodiments of the present invention.

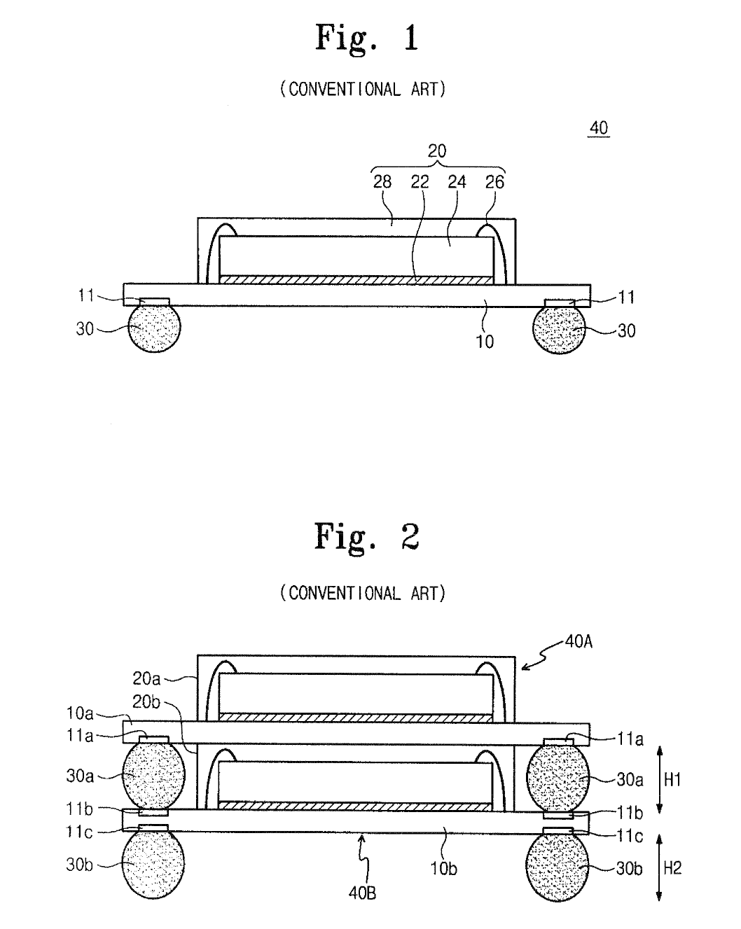

### DETAILED DESCRIPTION

Preferred embodiments of the present invention will be described below in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

Also, though terms like a first, a second, and a third are used to describe various regions and materials in various embodiments of the present invention, the regions and the materials are not limited to these terms. These terms are used only to distinguish one region from another region. Therefore, a region referred to as a first region in one embodiment may be referred to as a second region in another embodiment.

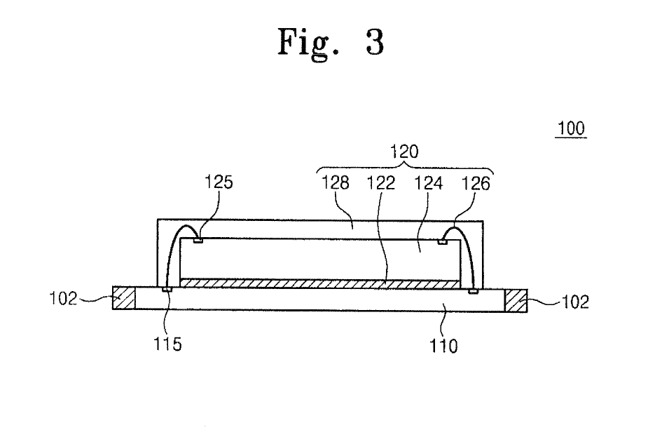

FIG. 3 is a cross-sectional view of a single semiconductor package according to some embodiments of the present invention.

Referring to FIG. 3, the single semiconductor package 100 includes a semiconductor chip 120 attached on a substrate 110. The substrate 110 may be implemented using a multi-layer circuit board. The semiconductor chip 120 includes a semiconductor die 124 attached on the substrate 110. An adhesive 122 may be used for attaching the semiconductor die 124. The adhesive 122 may be an adhesive tape, and may alternatively be formed of a material such as a liquid epoxy and the like. Bond pads 125 of the semiconductor die 124 are connected to bond fingers 115 of the substrate 110 through wires 126. The semiconductor die 124 and the wires 126 are encapsulated with an encapsulant 128 so that they can be shielded from the surrounding environment. The encapsulant 128 may be formed of an encapsulating resin. The single semiconductor package 100 further includes landing pads (not shown) formed in a lower surface of the substrate 100.

According to embodiments of the present invention, the substrate 110 of the single semiconductor package 100 includes landings 102 provided on both sides thereof. Each of the landings 102 may have a shape depressed toward the inside of the substrate 110 from a side surface or an upper or lower surface of the substrate 110. The dimensions of the depressed portions may be substantially equal to or slightly larger than those of solder balls to be disposed on the landings 102.

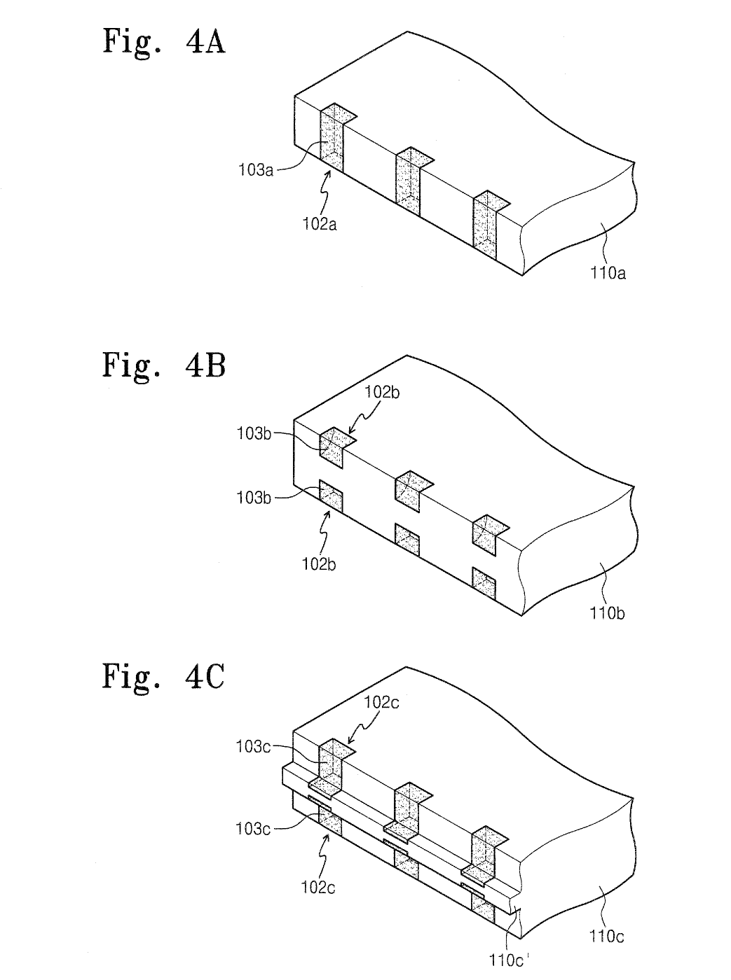

FIGS. 4A through 4C are partial perspective views illustrating landings of a single semiconductor package according to some embodiments of the present invention.

Referring to FIGS. 4A through 4C, various shaped landing structures having a plurality of depressed portions are explained as representing first, second, and third landings 102a, 102b, and 102c. Although the landing structures are shown as having depressed portions, the depressed portions are not necessarily included. For example, the landing structures may be formed on surfaces of the substrates in the shapes shown, without having depressed portions. Referring to FIG. 4A, the depressed portions of the first landings 102a may be I-type grooves extended from an upper surface to a lower surface of a substrate 110a on both sides of the substrate 110a. The I-type grooves may have a square shape in cross-section. However, the cross-sectional shape of the grooves is not limited to the square shape, and may take other geometrical shapes. The first landings 102a may further include ball lands 103a provided in the I-type grooves. The ball lands 103a may be formed of a metallic or other conductive material. In this case, the ball lands 103a contact solder balls so that they are electrically connected to each other. The ball lands 103a serve as connectors for electrically connecting a semiconductor chip to a system and a module. The metallic material may include copper (Cu) or gold (Au)-coated copper. The gold coated on the copper protects the copper from being directly exposed to air so that it can prevent oxidation of the copper.

Referring to FIG. 4B, the second landings 102b have a plurality of depressed portions. The depressed portions may be pocket-type grooves formed in upper and lower edges of both sides of a substrate 110b. A lower surface of the pocket-type groove may be inclined with respect to an upper surface of the substrate 110b. The second landings 102b may further include a plurality of ball lands 103b formed in the pocket-type grooves. The ball lands 103b may be the same as that described above with respect to FIG. 4A.

Referring to FIG. 4C, the substrate 110c of the semiconductor package may include a protrusion 110c′ having a smaller thickness than that of a substrate 110c on a side surface thereof.

Each of depressed portions of the third landings 102c may have one set of stair-type grooves formed in an upper surface of the protrusion 110c′ and an upper portion of the side surface of the substrate 110c, and another set of stair-type grooves formed in a lower surface of the protrusion 110c′ and a lower portion of the side surface of the substrate 110c. The third landings 102c may further include a plurality of ball lands 103c formed in the stair-type grooves. The ball lands 103c may be the same as that described above with respect to FIG. 4A. These structures having the pocket-type grooves of the second landings 102b, illustrated in FIG. 4B, and the stair-type grooves of the third landings 102c, illustrated in FIG. 4C, allow two or more solder balls to be more stably disposed on the substrates 110b and 110c than conventional structures.

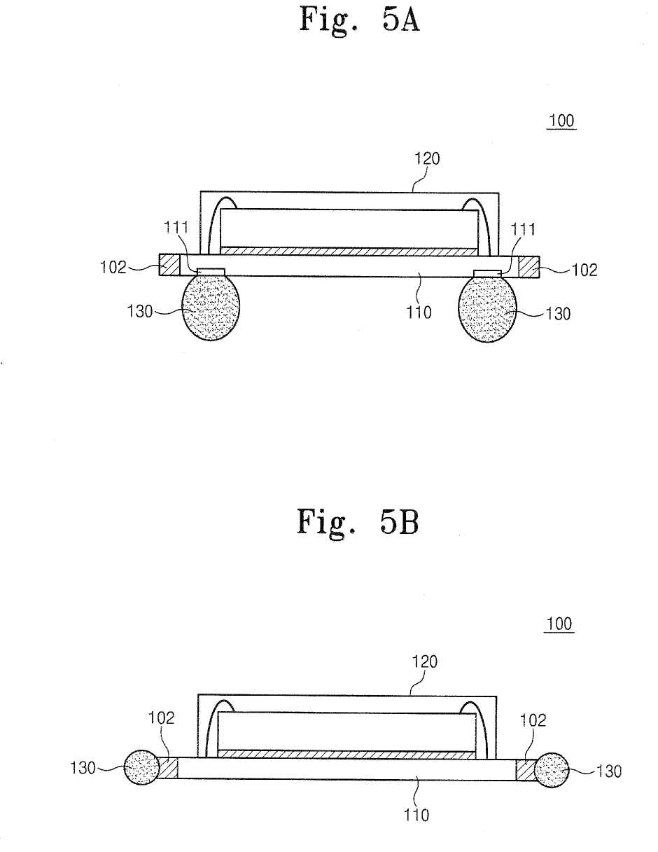

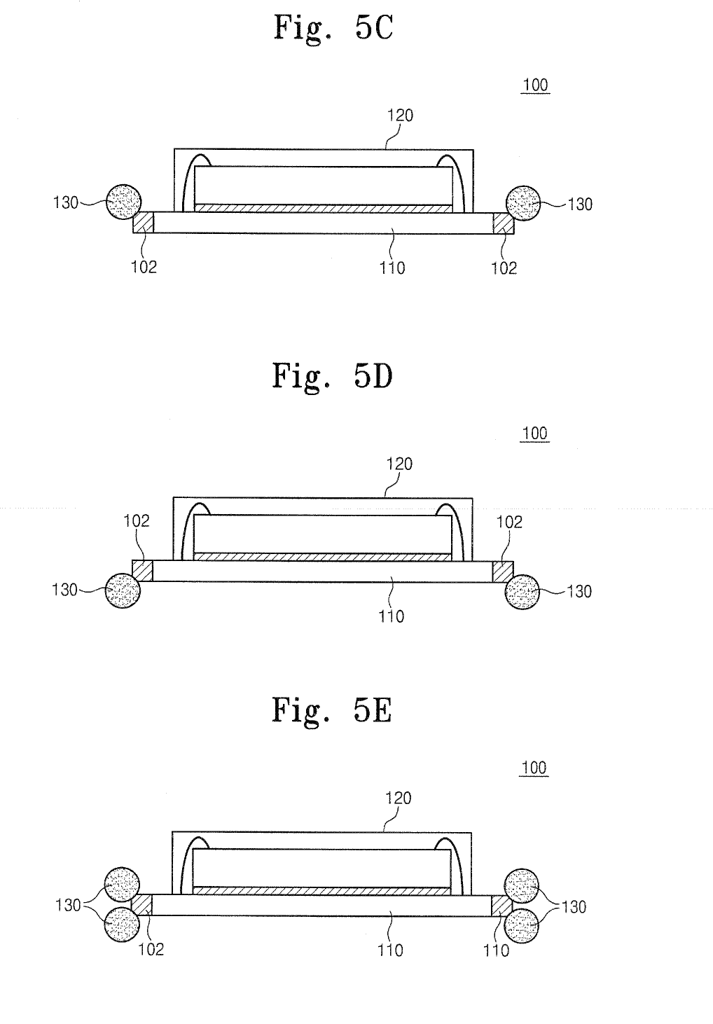

FIGS. 5A through 5E are cross-sectional views illustrating various positions of solder balls in a single semiconductor package according to some embodiments of the present invention. A single semiconductor package 100 includes a semiconductor chip 120 disposed on the substrate 110, and landing pads 111 formed in a lower surface of the substrate 110. Referring to FIG. 5A, solder balls 130 contacting the landing pads 111 may be disposed on a lower surface of the substrate 110. Referring to FIG. 5B, the solder balls 130 contacting landings 102 may be disposed on both side surfaces of the substrate 110. Each of the landings 102 may have an “I”-shape. Referring to FIGS. 5C through 5E, the solder balls 130 contacting the landings 102 may be disposed on upper edges, lower edges, and upper and lower edges of the substrate 110, respectively.

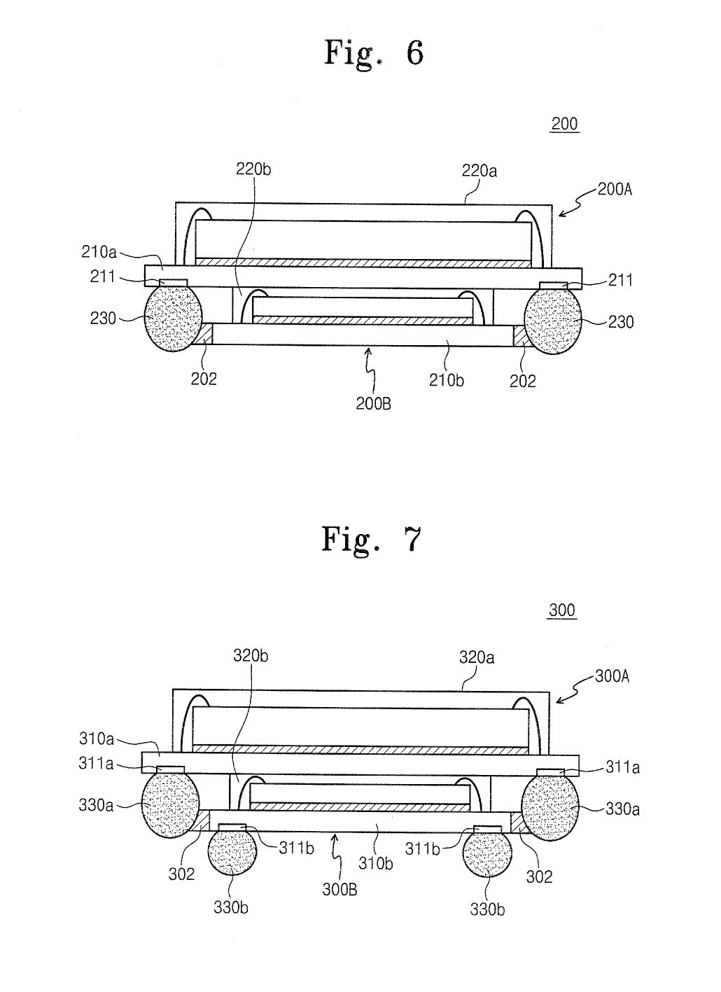

FIGS. 6 through 10 are cross-sectional views of a stacked BGA semiconductor package according to some embodiments of the present invention. As shown in FIGS. 6 through 10, a plurality of semiconductor packages are stacked in the stacked BGA semiconductor package. The semiconductor packages may be substantially the same as those described in FIGS. 3, 4A, 4B and 4C.

Referring to FIG. 6, a stacked BGA semiconductor package 200, where a first semiconductor package 200A and a second semiconductor package 200B are stacked, will be described below. The stacked BGA semiconductor package 200 includes the first semiconductor package 200A and the second semiconductor package 200B. The first semiconductor package 200A may include a first substrate 210a, a first semiconductor chip 220a disposed on the first substrate 210a, and landing pads 211 formed in a lower surface of the first substrate 210a. The second semiconductor package 200B is disposed below the first semiconductor package 200A. The second semiconductor package 200B may include a second substrate 210b and a second semiconductor chip 220b disposed on the second substrate 210b. The second substrate 210b includes landings 202 on both sides thereof where depressed grooves are provided, wherein the landings 202 are formed of a metallic or other conductive material. The stacked BGA semiconductor package 200 further includes stacked solder balls 230. The stacked solder balls 230 are connected to the landing pad 211 in the lower surface of the first substrate 210a and the landings 202 on both sides of the substrate 210b. Consequently, the stacked solder balls 230 serve as physical and electrical connectors. The stacked solder balls 230 may be further connected to a motherboard (not shown) and/or another package.

Referring to FIG. 7, a stacked BGA semiconductor package 300 where a first semiconductor package 300A and a second semiconductor package 300B are stacked will be described below. The stacked BGA semiconductor package 300 includes the first semiconductor package 300A and the second semiconductor package 300B. The first semiconductor package 300A may include a first substrate 310a, a first semiconductor chip 320a disposed on the first substrate 310a, and first landing pads 311a formed in a lower surface of the first substrate 310a. The second semiconductor package 300B is disposed below the first semiconductor package 300A. The second semiconductor package 300B may include a second substrate 310b, a second semiconductor chip 320b disposed on the second substrate 210b, and a second landing pad 311b in a lower portion of the second semiconductor package 300B. The second substrate 310b includes landings 302 on both sides thereof where depressed grooves are provided, wherein the landings 302 are formed of a metallic or other conductive material. The stacked BGA semiconductor package 300 further includes first solder balls 330a and second solder balls 330b. The first solder balls 330a are connected to the first landing pads 311a in the lower surface of the first substrate 310a and the landings 202 on the both sides of the second substrate 310b. The second solder balls 330b contact the second landing pads 311b and serve as physical and electrical connectors. The second solder balls 330b may be further connected to a motherboard (not shown) and/or another package.

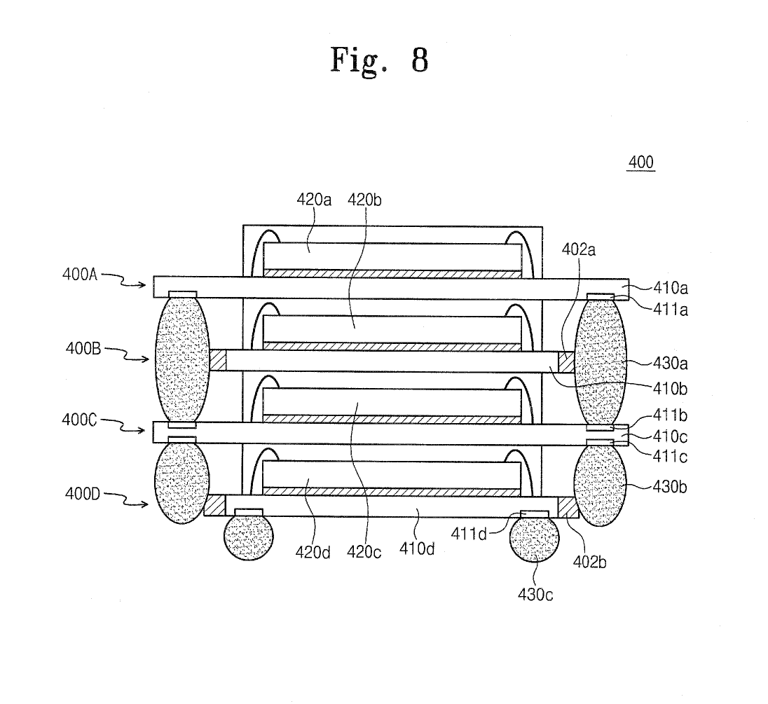

Referring to FIG. 8, a stacked BGA semiconductor package 400 will be described below. The stacked BGA semiconductor package 400 includes a first semiconductor package 400A, a second semiconductor package 400B, and a third semiconductor package 400C. The first semiconductor package 400A may include a first substrate 410a, a first semiconductor chip 420a disposed on the first substrate 410a, and first landing pads 411a formed in a lower surface of the first substrate 410a. The second semiconductor package 400B is disposed below the first semiconductor package 400A. The second semiconductor package 400B may include a second substrate 410b and a second semiconductor chip 420b disposed on the second substrate 410b. The second substrate 410b includes first landings 402a on both sides thereof where depressed grooves are provided, wherein the first landings 402a are formed of a metallic material. The third semiconductor package 400C may include a third substrate 410c, a third semiconductor chip 420c disposed on the third substrate 410c, second landing pads 411b formed in an upper surface of the third substrate 410c, and third landing pads 411c formed in a lower surface of the third substrate 410c. The stacked BGA semiconductor package 400 further includes first solder balls 430a. The first solder balls 430a contact the first landing pads 411a formed in the lower surface of the first substrate 410a, the first landings 402a formed on both sides of the second substrate 410b, and the second landing pads 411b formed in the upper surface of the third substrate 410c to connect the first landing pads 411a, the first landings 402a, and the second landing pads 411b.

The stacked BGA semiconductor package 400 may further include second solder balls 430b. The second solder balls 430b contact the third landing pads 411c formed in the lower surface of the third substrate 410c. The second solder balls 430b may be further connected to a motherboard (not shown) and/or another package.

The stacked BGA semiconductor package 400 may further include a fourth semiconductor package 400D disposed below the third semiconductor package 400C. The fourth semiconductor package 400D may include a fourth substrate 410d and a fourth semiconductor chip 420d disposed on the fourth substrate 410d. The fourth substrate 410d includes second landings 402b on both sides thereof where depressed grooves are provided, wherein the second landings 402b are formed of a metallic or other conductive material. The second solder balls 430b contact the second landings 402b as well as the third landing pads 411c formed in a lower surface of the third substrate 410c.

Furthermore, the fourth semiconductor package 400D may also include fourth landing pads 411d formed in a lower surface of the fourth substrate 410d. The stacked BGA semiconductor package 400 may further include third solder balls 430c contacting the fourth landing pads 411d. The third solder balls 430c may be further connected to a motherboard (not shown) and/or another package.

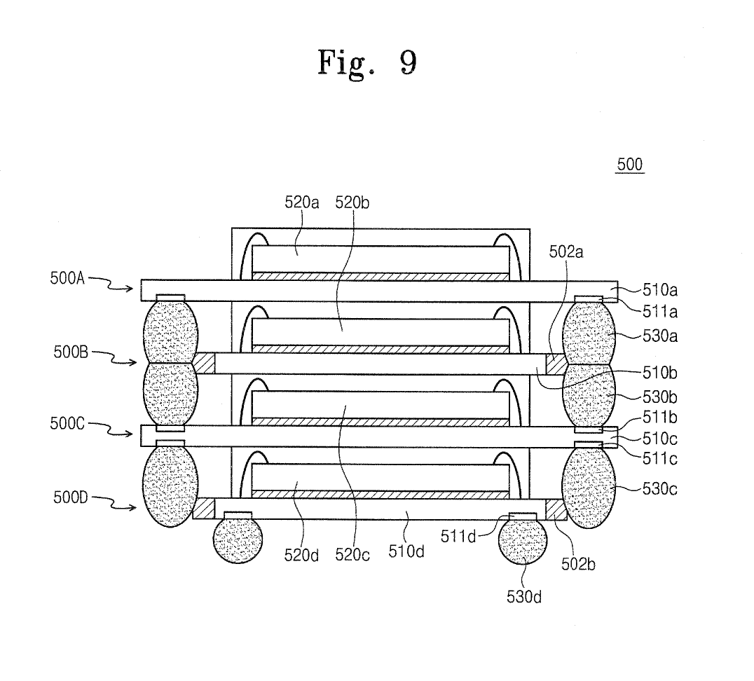

Referring to FIG. 9, a stacked BGA semiconductor package 500 will be described below. The stacked BGA semiconductor package 500 includes a first semiconductor package 500A, a second semiconductor package 500B, and a third semiconductor package 500C. The first semiconductor package 500A may include a first substrate 510a, a first semiconductor chip 520a disposed on the first substrate 510a, and first landing pads 511a formed in a lower surface of the first substrate 510a. The second semiconductor package 500B is disposed below the first semiconductor package 500A. The second semiconductor package 500B may include a second substrate 510b and a second semiconductor chip 520b disposed on the second substrate 510b. The second substrate 510b includes first landings 502a on both sides thereof where depressed grooves are provided, wherein the first landings 502a are formed of a metallic material. The third semiconductor package 500C may include a third substrate 510c, a third semiconductor chip 520c disposed on the third substrate 510c, second landing pads 511b formed in an upper surface of the third substrate 510c, and third landing pads 511c formed in a lower surface of the third substrate 510c. The stacked BGA semiconductor package 500 further includes first and second solder balls 530a and 530b. The first solder balls 530a contact the first landing pads 511a formed in the lower surface of the first substrate 510a and the first landings 502a formed in both sides of the second substrate 510b. The second solder balls 530b contact the first landings 502a formed in both sides of the second substrate 510b and the second landing pads 511b formed in the upper surface of the third substrate 510c.

The stacked BGA semiconductor package 500 may further include third solder balls 530c. The third solder balls 530c contact the third landing pads 511c formed in the lower surface of the third substrate 510c to connect therebetween. The third solder balls 530c may be further connected to a motherboard (not shown) and/or another package.

Furthermore, the stacked BGA semiconductor package 500 may further include a fourth semiconductor package 500D disposed below the third semiconductor package 500C. The fourth semiconductor package 500D may include a fourth substrate 510d and a fourth semiconductor chip 520d disposed on the fourth substrate 510d. The fourth substrate 510d includes second landings 502b on both sides thereof where depressed grooves are provided, wherein the second landings 502b are formed of a metallic or other conductive material. The second solder balls 530b contact the second landings 502b as well as the third landing pads 511c formed in the lower surface of the third substrate 510c to connect therebetween.

Furthermore, the fourth semiconductor package 500D may further include fourth landing pads 511d formed in a lower surface of the fourth substrate 510d. The stacked BGA semiconductor package 500 may further include fourth solder balls 530d contacting the fourth landing pads 511d. The fourth solder balls 530d may be further connected to a motherboard (not shown) and/or another package.

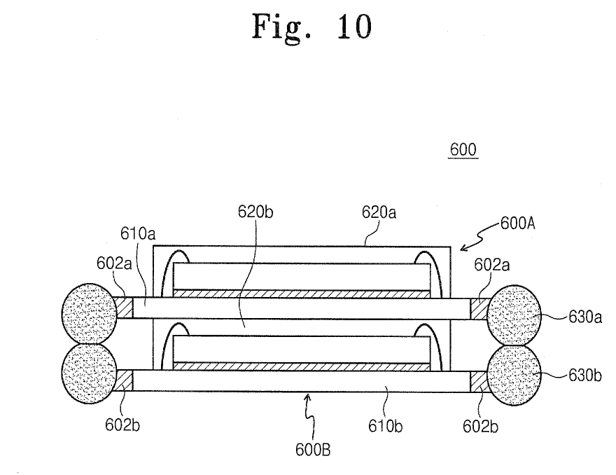

Referring to FIG. 10, a stacked BGA semiconductor package 600 where a first semiconductor package 600A and a second semiconductor package 600B are stacked will be described below. The stacked BGA semiconductor package 600 includes the first semiconductor package 600A and the second semiconductor package 600B. The first semiconductor package 600A may include a first substrate 610a and a first semiconductor chip 620a disposed on the first substrate 610a. The first substrate 610a includes first landings 602a on both sides thereof where depressed grooves are provided, wherein the first landings 602a are formed of a metallic or other conductive material. The second semiconductor package 600B is disposed below the first semiconductor package 600A.

The second semiconductor package 600B may include a second substrate 610b and a second semiconductor chip 620b disposed on the second substrate 610b. The second substrate 610b includes second landings 602b on both sides thereof where depressed grooves are provided, wherein the second landings 602b are formed of a metallic or other conductive material.

The stacked BGA semiconductor package 600 further includes solder balls 630a and 630b connecting the first landings 602a to the second landings 602b. The solder balls 630a and 630b are provided in pairs, each of the solder balls 630a and 630b being in contact with the first landings 602a and the second landings 602b.

According to embodiments of the present invention described above, the semiconductor packages are stably stacked by the grooves formed in edges of the substrates and landings having ball lands formed in the grooves. Also, the overall thickness of the stacked BGA semiconductor package is much less than conventional packages thereby helping to realize miniaturization and reduced thickness of semiconductor packages.

Embodiments of the present invention provide semiconductor packages. The semiconductor packages include: a substrate including landings disposed in depressed grooves of both sides of the substrate, and bond fingers disposed on an upper surface of the substrate, wherein the landings include a conductive material; a semiconductor chip disposed on the substrate and including bond pads; wires connecting the bond pads to the bond fingers; and an encapsulant encapsulating the semiconductor chip and the wires.

In some embodiments, the depressed grooves may have shapes depressed toward an inside of the substrate from the side surface, the upper surface, or a lower surface of the substrate. The depressed grooves may be I-type grooves, pocket-type grooves, and stair-type grooves. The I-type grooves may be extended from the upper surface to the lower surface of the substrate on both sides of the substrate. The pocket-type grooves may be disposed in upper and lower edges of both sides of the substrate. The substrate may comprise protrusions disposed on both sides of the substrate and having a smaller thickness than that of the substrate, and stair-type grooves may be disposed in upper surfaces of the protrusions and an upper portion of both sides of the substrate and/or stair-type grooves may be disposed in lower surfaces of the protrusions and a lower portion of both sides of the substrate.

According to some embodiments, the conductive material may be coated on the depressed grooves. The conductive material may comprise copper or gold coated on copper. The semiconductor package may further comprise solder balls disposed on the lower surface of the substrate. The semiconductor package may further comprise solder balls disposed on the landings. The semiconductor package may further comprise solder balls disposed on one or more of upper and lower portions of the landings.

In other embodiments of the present invention, stacked semiconductor packages include a first semiconductor package, a second semiconductor package, and first solder balls. The first semiconductor package includes: a first substrate; a first semiconductor chip disposed on the first substrate; and first landing pads disposed in a lower surface of the first substrate. The second semiconductor package is disposed below the first semiconductor package and includes: a second substrate having first landings formed in depressed grooves of both sides of the second substrate, the first landings being a conductive material and a second semiconductor chip disposed on the second substrate. The first solder balls connect the first landing pads to the first landings.

In some embodiments, the first semiconductor package is disposed below the second semiconductor package. The second semiconductor package may comprise second landing pads disposed in a lower surface of the second substrate, and the stacked semiconductor package may further comprise second solder balls disposed on the second landing pads. The stacked semiconductor package may further include a third semiconductor package including: a third substrate; a third semiconductor chip disposed on the third substrate; and third landing pads formed in an upper surface of the third substrate. The first solder balls may be connected to the third landing pads.

In other embodiments, the third semiconductor package may comprise fourth landing pads disposed in a lower surface of the third substrate. The stacked semiconductor package may further comprise third solder balls disposed on the fourth landing pads.

In still other embodiments, the stacked semiconductor package may further include a fourth semiconductor package and a fourth semiconductor chip. The fourth semiconductor package is disposed below the third semiconductor package. The fourth semiconductor package includes a fourth substrate having second landings disposed in depressed grooves of both sides of the fourth substrate, the second landings comprising a conductive material. The fourth semiconductor chip is disposed on the fourth substrate. The third solder balls may be connected to the second landings.

According to some embodiments, the fourth semiconductor package may comprise fifth landing pads disposed in a lower surface of the fourth substrate, and the stacked semiconductor package may further comprise fourth solder balls disposed on the fifth landing pads.

According to still other embodiments, a stacked semiconductor package comprises: a first semiconductor package, a second semiconductor package disposed below the first semiconductor package, and solder balls connecting the first landings to the second landings. The first semiconductor package includes: a first substrate having first landings disposed in depressed grooves of both sides of the first substrate, the first landings comprising a conductive material; and a first semiconductor chip disposed on the first substrate. The second semiconductor package includes: a second substrate having second landings disposed in depressed grooves of both sides of the second substrate, the second landings comprising a conductive material; and a second semiconductor chip disposed on the second substrate. The solder balls may be disposed in pairs, each of the solder balls being in contact with the first landings and the second landings.

According to some embodiments of the present invention, a semiconductor package comprises: a substrate including landings disposed on both sides of the substrate, and bond fingers disposed on an upper surface of the substrate, wherein the landings include a conductive material; a semiconductor chip disposed on the substrate and including bond pads; wires connecting the bond pads to the bond fingers; and an encapsulant encapsulating the semiconductor chip and the wires. The landings may be disposed on upper and lower edges of both sides of the substrate. The substrate may comprise protrusions disposed on both sides of the substrate and having a smaller thickness than that of the substrate, and the landings may be disposed on upper surfaces of the protrusions and an upper portion of both sides of the substrate and the landings may be disposed on lower surfaces of the protrusions and a lower portion of both sides of the substrate. The semiconductor package may further comprise solder balls disposed on the landings. The semiconductor package may further comprise solder balls disposed on one or more of upper and lower portions of the landings.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor package comprising:
a substrate including landings disposed in depressed grooves of both sides of the substrate, and bond fingers disposed on an upper surface of the substrate, wherein the landings include a conductive material;
a semiconductor chip disposed on the substrate and including bond pads;
wires connecting the bond pads to the bond fingers; and
an encapsulant encapsulating the semiconductor chip and the wires.

2. The semiconductor package of claim 1, wherein the depressed grooves have shapes depressed toward an inside of the substrate from the side surface, the upper surface, or a lower surface of the substrate.

3. The semiconductor package of claim 2, wherein the depressed grooves are I-type grooves extended from the upper surface to the lower surface of the substrate on both sides of the substrate.

4. The semiconductor package of claim 2, wherein the depressed grooves are disposed in upper and lower edges of both sides of the substrate and the depressed grooves are pocket-type grooves of which lower surfaces are inclined with respect to the substrate.

5. The semiconductor package of claim 2, wherein the substrate comprises protrusions disposed on both sides of the substrate and having a smaller thickness than that of the substrate, and wherein the depressed grooves have stair-type grooves disposed in upper surfaces of the protrusions and an upper portion of both sides of the substrate and stair-type grooves disposed in lower surfaces of the protrusions and a lower portion of both sides of the substrate.

6. The semiconductor package of claim 1, wherein the conductive material is coated on the depressed grooves.

7. The semiconductor package of claim 1, wherein the conductive material comprises copper or gold coated on copper.

8. The semiconductor package of claim 1, further comprising solder balls disposed on the lower surface of the substrate.

9. The semiconductor package of claim 1, further comprising solder balls disposed on the landings.

10. The semiconductor package of claim 1, further comprising solder balls disposed on one or more of upper and lower portions of the landings.

11. A stacked semiconductor package comprising:
a first semiconductor package including:
a first substrate;
a first semiconductor chip disposed on the first substrate; and
first landing pads disposed in a lower surface of the first substrate;
a second semiconductor package disposed below the first semiconductor package, the second semiconductor package including:
a second substrate having first landings disposed in depressed grooves of both sides of the second substrate, the first landings comprising a conductive material; and
a second semiconductor chip disposed on the second substrate; and
first solder balls connecting the first landing pads to the first landings.

12. The stacked semiconductor package of claim 11, wherein the second semiconductor package comprises second landing pads disposed in a lower surface of the second substrate, and the stacked semiconductor package further comprises second solder balls disposed on the second landing pads.

13. The stacked semiconductor package of claim 11, further comprising a third semiconductor package disposed below the second semiconductor package, the third semiconductor package including:
a third substrate;
a third semiconductor chip disposed on the third substrate; and
third landing pads disposed in an upper surface of the third substrate,
wherein the first solder balls are connected to the third landing pads.

14. The stacked semiconductor package of claim 13, wherein the third semiconductor package comprises fourth landing pads disposed in a lower surface of the third substrate, and the stacked semiconductor package further comprises third solder balls disposed on the fourth landing pads.

15. The stacked semiconductor package of claim 14, further comprising a fourth semiconductor package disposed below the third semiconductor package, the fourth semiconductor package including:
a fourth substrate having second landings disposed in depressed grooves of both sides of the fourth substrate, the second landings comprising a conductive material; and
a fourth semiconductor chip disposed on the fourth substrate,
wherein the third solder bails are connected to the second landings.

16. The stacked semiconductor package of claim 15, wherein the fourth semiconductor package comprises fifth landing pads disposed in a lower surface of the fourth substrate, and the stacked semiconductor package further comprises fourth solder balls disposed on the fifth landing pads.

17. The stacked semiconductor package of claim 11, further comprising:
a third semiconductor package disposed below the second semiconductor package, the third semiconductor package including:
a third substrate;
a third semiconductor chip disposed on the third substrate; and
third landing pads disposed in an upper surface of the third substrate; and
second solder balls connecting the first landings to the third landing pads.

18. The stacked semiconductor package of claim 17, wherein the third semiconductor package comprises fourth landing pads disposed in a lower surface of the third substrate, and the stacked semiconductor package further comprises third solder balls disposed on the fourth landing pads.

19. The stacked semiconductor package of claim 18, further comprising a fourth semiconductor package disposed below the third semiconductor package, the fourth semiconductor package including:
a fourth substrate having second landings disposed in depressed grooves of both sides of the fourth substrate, the second landings comprising a conductive material; and
a fourth semiconductor chip disposed on the fourth substrate,
wherein the third solder balls are connected to the second landings.

20. The stacked semiconductor package of claim 19, wherein the fourth semiconductor package comprises fifth landing pads disposed in a lower surface of the fourth substrate, and the stacked semiconductor package further comprises fourth solder balls disposed on the fifth landing pads.

21. A stacked semiconductor package comprising:
a first semiconductor package including:
a first substrate having first landings disposed in depressed grooves of both sides of the first substrate, the first landings comprising a conductive material; and
a first semiconductor chip disposed on the first substrate;
a second semiconductor package disposed below the first semiconductor package, the second semiconductor package including:
a second substrate having second landings disposed in depressed grooves of both sides of the second substrate, the second landings comprising a conductive material; and
a second semiconductor chip disposed on the second substrate; and
solder balls connecting the first landings to the second landings.

22. The stacked semiconductor package of claim 21, wherein the solder balls are disposed in pairs, each of the solder balls being in contact with the first landings and the second landings.

23. A semiconductor package comprising:
a substrate including landings disposed on both sides of the substrate, and bond fingers disposed on an upper surface of the substrate, wherein the landings include a conductive material;
a semiconductor chip disposed on the substrate and including bond pads, the bond pads electrically connected to the bond fingers; and
an encapsulant encapsulating the semiconductor chip.

24. The semiconductor package of claim 23, wherein the landings are disposed on upper and lower edges of both sides of the substrate.

25. The semiconductor package of claim 23, wherein the substrate comprises protrusions disposed on both sides of the substrate and having a smaller thickness than that of the substrate, and wherein the landings are disposed on upper surfaces of the protrusions and an upper portion of both sides of the substrate and the landings are disposed on lower surfaces of the protrusions and a lower portion of both sides of the substrate.

26. The semiconductor package of claim 23, further comprising solder balls disposed on the landings.

27. The semiconductor package of claim 23, further comprising solder balls disposed on one or more of upper and lower portions of the landings.
